(19) United States
(12) Patent Application Publication
(10) Pub. No.: US 2015/0129527 A1
(43) Pub. Date: May 14, 2015

(54) FRAME STRUCTURE OF SOLAR CELL MODULE

(71) Applicant: ATOMIC ENERGY COUNCIL - INSTITUTE OF NUCLEAR ENERGY RESEARCH, TAOYUAN COUNTY (TW)

(72) Inventors: ZUN-HAO SHIH, TAOYUAN COUNTY (TW); HWEN-FEN HONG, TAOYUAN COUNTY (TW); YUEH-MU LEE, TAOYUAN COUNTY (TW)

(73) Assignee: ATOMIC ENERGY COUNCIL - INSTITUTE OF NUCLEAR ENERGY RESEARCH, TAOYUAN COUNTY (TW)

(21) Appl. No.: 14/076,391

(22) Filed: Nov. 11, 2013

(51) Int. Cl. F24J 2/52; F24J 2/46; H01L 31/02

(52) U.S. Cl. CPC F24J 2/52; F24J 2/5252; H01L 31/02; F24J 2/464
USPC 211/182

(57) ABSTRACT

The present invention relates to a frame structure of solar cell module, which adopts extruded aluminum as the frame member of solar cell module. At the junctions of the length, width, and height edges, connecting members using the three-axis joining and tenoning technology are used as fixing members. The tenon parts in both horizontal directions of the three-axis connecting member are first inserted into and joined with the mortises of the length-edge bar and the width-edge bar of extruded aluminum. Then the mortises in the height-edge bar are joined with the tenon parts of the connecting member in the vertical direction and thus completing assembling of the frame of solar cell module.

### FIELD OF THE INVENTION

The present invention relates generally to a frame structure of solar cell module, and particularly to a frame structure of solar cell module that adopts a three-axis connecting member having tenon parts for combining with the edge bars in the length, width, and height directions.

### BACKGROUND OF THE INVENTION

The high concentrating solar cell is a novel technology having the potential of replacing traditional power plants. It overthrows the traditional method of direct sunlight illumination. Instead, it uses the Fresnel lens to concentrate the sunlight to solar cells and multiply the intensity of the sunlight by hundreds of times for enhancing the photoelectric conversion efficiency.

Because the technology is applied to power-plant-grade power generating stations and solar-cell modules are cores of a power generating system, the mass production and weather tolerance of solar-cell modules determine the development of the power generating technology of high concentrating solar energy.

High concentrating solar cells adopt lenses to focus the sunlight. Thereby, they are installed on the outdoor frame in modules. The sun tracking system is used for ensuring light concentrating effect and thus maintaining excellent energy conversion efficiency. Because the adopted frame for solar cell modules is influenced by outdoor rains, its durability is challenged.

Currently, in the frames of solar cell modules, multiple screw heads are exposed around the apexes. This is because the height edges of the frames adopt external prisms, and the external prisms are fixed on the top and bottom frames by screws. The process of this assembly method is more complicated and exposes the screw heads. If there are acute angle at the exposed screw heads, workers are easily harmed while moving them. In addition, owing to long-term stress by winds, the sun, and rains, the screws tend to rust and erode, which increases difficulty in disassembling for maintenance in the future.

Another connecting method in assembling is to use L-shaped accessories as the connecting members for the two edge bars. Nonetheless, generally, L-shaped accessories are screwed and fixed to the edge bars directly, which produces the problem of bad space utilization in the subsequent procedure of placing solar cell modules. In addition, if three-axis reinforcement is desired, three L-shaped accessories are required at each corner, consuming substantial manufacturing time and complexity in assembling.

Accordingly, the present invention provides improvement for the frame of solar cell module. Bad space utilization can be avoided; safety, convenience, and weather tolerance can be enhanced. Thereby, a frame structure of solar cell module having novel structure and excellent performance is provided.

### SUMMARY

An objective of the present invention is to provide a frame structure of solar cell module, which uses a three- or multi-axis connecting member having tenon parts in respective directions for combining with the edge bars for preventing exposure of screw heads on the outer sides of respective apexes of the frame of solar cell module. Thereby, incises wounds caused by rusted and eroded screw heads during transportation can be avoided.

Another objective of the present invention is to provide a frame structure of solar cell module, which has no any L-shaped accessory for reinforcing structure on the inner edges of respective apexes. Thereby, the usable space in the frame is increased and thus reducing the difficulty in installing solar cell modules.

Still another objective of the present invention is to provide a frame structure of solar cell module. The adopted three-axis connecting member in the structure can be further extended to a multi-axis connecting member for being applicable to various embodiments of edge-bar intersections. Thereby, the application is flexible.

For achieving the objectives described above, the present invention discloses a frame structure of solar cell module, which comprises a plurality of three-axis connecting members and a plurality of edge bars. Each of the plurality of three-axis connecting members comprises three connecting parts and a plurality of tenon parts, respectively. The three connecting parts are rectangular. A first fixing screw hole penetrates the center of an inner surface of each of the plurality of connecting parts, respectively. The plurality of tenon parts are pillars disposed on an outer surface of the plurality of connecting parts, respectively. Both sides of the plurality edge bars have a plurality of mortises and a second fixing screw hole. The plurality of tenon parts are inserted into the plurality of mortises, respectively; and the second fixing screw hole corresponds to the first fixing screw hole. By using the arrangement of this structure, the assembly quality of the frame of solar cell module can be further improved.

### BRIEF DESCRIPTION OF THE DRAWINGS

FIG. 1 shows a structural schematic diagram of the three-axis connecting member according to the present invention;

FIG. 2 shows a structural schematic diagram of the edge bar according to the present invention;

FIG. 3 shows a structural schematic diagram of the edge bar having grooves according to the present invention;

FIG. 4 shows a structural schematic diagram of combining the three-axis connecting member with the edge bars according to the present invention;

FIG. 5 shows a structural schematic diagram of the cylindrical tenon part according to the present invention;

FIG. 6 shows a structural schematic diagram of the prismatic tenon part according to the present invention;

FIG. 7 shows a structural schematic diagram of covering the three-axis connecting member using the protection cap according to the present invention; and

FIG. 8 shows a structural schematic diagram of the multi-axis connecting member according to the present invention.

### DETAILED DESCRIPTION

In order to make the structure and characteristics as well as the effectiveness of the present invention to be further understood and recognized, the detailed description of the present invention is provided as follows along with embodiments and accompanying figures.

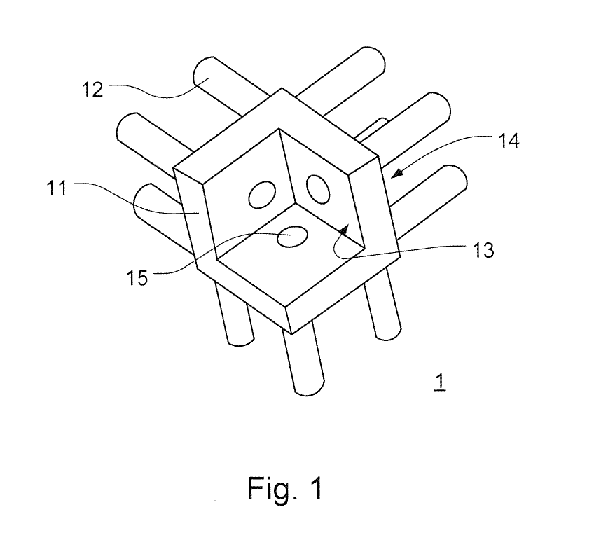

First, please refer to FIG. 1, which discloses the technical characteristics of the structure of the three-axis connecting member 1 according to the present invention. As shown in the figure, the three-axis connecting member 1 mainly comprises three connecting parts 11 and a plurality of tenon parts 12. The shape of the plurality of connecting parts 11 is rectangular and the plurality of connecting parts 11 include two main, namely, the inner and the outer, surfaces, respectively. A first fixing screw hole 15 penetrates the connecting part 11 on the inner surface 13. The plurality of tenon parts are disposed vertically on the outer surface 14 of the connecting part 11.

According to the present invention, the three-axis connecting part 1 is the key components to form the frame of solar cell module. It is considered that the exposed screw heads may lead to incised wounds during the process of installing a solar cell module to a frame. Alternatively, because L-shaped accessories are disposed on the inner side of the frame for reinforcement, the space at the corners in the frame is occupied and the integrity is destroyed. Thereby, the usable space is reduced and retarding the installation planning of solar cell modules. Accordingly, by using the structural characteristics of the three-axis connecting member 1, a complete space at the inner corners can be provided for solar cell modules after the frame is assembled.

As shown in FIG. 1, the three connecting parts 11 of the three-axis connecting member 1 are perpendicular to one another. Hence, they are suitable to be placed at the four apexes of the periphery of the rectangular frame according to the prior art. Each of the plurality of apexes has three edges connecting with the three-axis connecting member 1. Then, the tenon parts 12 of the three-axis connecting member 1 can be combined with the three edges and used as the pivot for fixing the three edges to a single point.

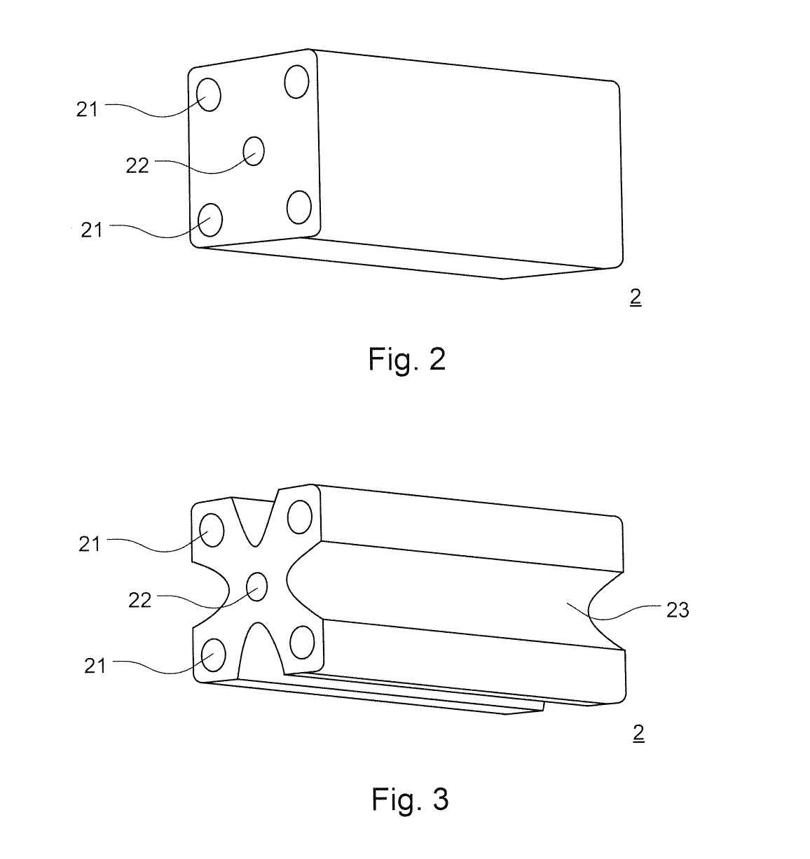

Please refer to FIG. 2, which shows a structural schematic diagram of the edge bar 2 according to the present invention. The edge bar 2 is a long bar-shaped tube and manufactured by aluminum extrusion method using lightweight and high strength aluminum or aluminum alloy. Considering that the shape of the edge bar 2 is relatively simple and its cross-section is a fixed pattern, the low-cost and fast manufacturing speed aluminum extrusion method will suffice. Each of the both sides of the edge bar 22 has a plurality of mortises 21 and a second fixing screw hole 22 so that the plurality of tenon parts 12 shown in FIG. 1 can be inserted into the plurality of mortises 21, respectively. In addition, when the tenon parts 12 are inserted into the mortises 21, the location of the second fixing screw hole 22 is at the center and corresponding to the first fixing screw hole 15. Thereby, a screw can penetrate the first fixing screw hole 15 and the second fixing screw hole 22 concurrently.

FIG. 3 shows another embodiment of the edge bar 2, which has at least a groove 23 on its periphery. The groove 23 is parallel with the direction of the edge bar 22. Alternatively, under the condition of not influencing the mortise 21 and the second fixing screw hole 22, the groove 23 can be designed in other forms. One of the functions of the groove 23 is to facilitate the installation of the solar cell module, so that the solar cell module can be wedge and fixed in the frame along the groove 23. Another function of the groove 23 is to reduce the consumption of the material for the edge bar 2. Thereby, the cost can be reduced and the weight of the array of solar cell modules can be lowered as well. Because solar cell modules are supported by holders and operating with a sun tracking system, lighter modules reduce the burden of the holders and help to reduce the power consumption for rotation.

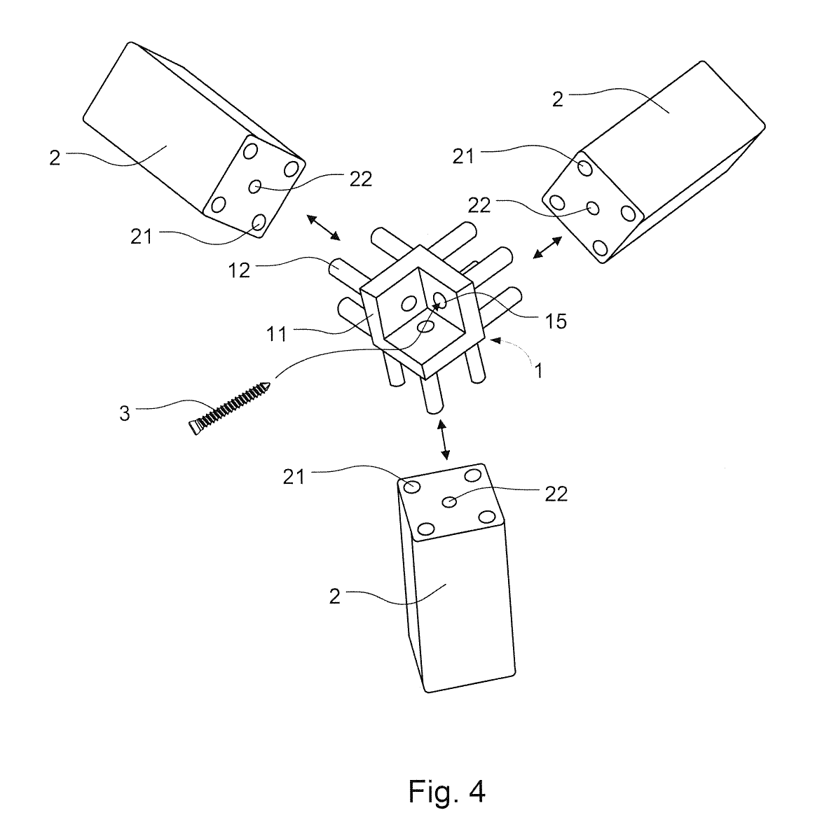

FIG. 4 shows a schematic diagram of the installing direction in assembling according to the present invention. As shown in the figure, the three edge bars 22 are connected to the three-axis connecting member 1 from three directions and fixed by passing screws 3 through the first and second fixing screw holes 15, 22 (only one of the screws 3 is shown in the figure). After adjusting to a proper angle, the tenon parts 12 are inserted into the mortises 21 of the edge bars 2. The inner diameter of the mortises 21 is identical to the width of the plurality of tenon parts 12, so that both can be roughly fixed before the screws 3 are engaged. After joining the three-axis connecting member 1 and the edge bars 2, the three-axis connecting member 1 becomes an apex of the frame of solar cell module. The three edge bars 2 become the length, width, and height edges, respectively, of the frame of solar cell module. If the assembled frame of solar module is in the form of a rectangular solid, four three-axis connecting members 1 and twelve edge bars 2 can be used.

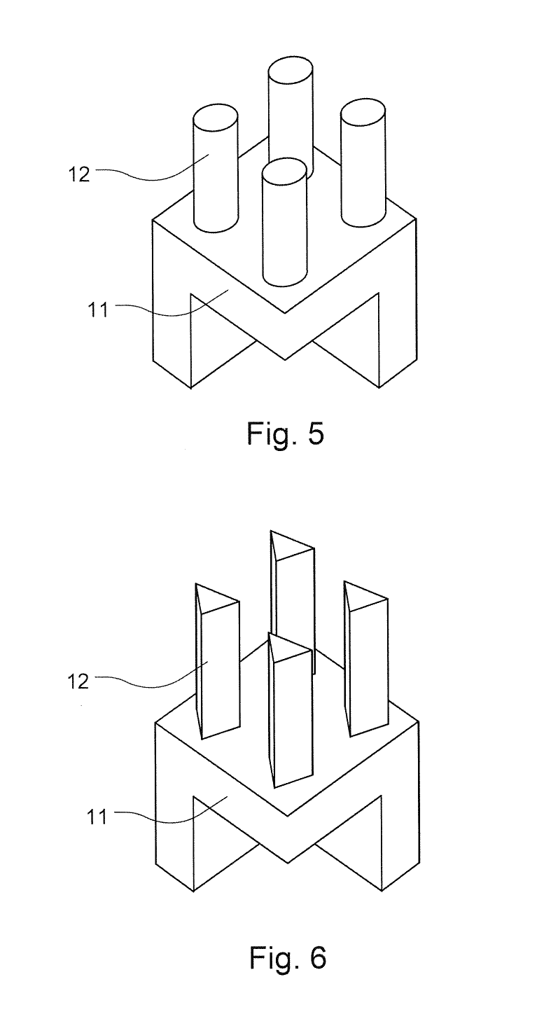

The tenon parts 12 according to the present invention is not limited to be cylindrical as shown in FIG. 5. They can be prismatic, as shown in FIG. 6. Then, the mortises 21 for inserting the tenon parts 12 on both sides of the edge bars 2 is adjusted according to the pattern of the tenon parts 12 correspondingly.

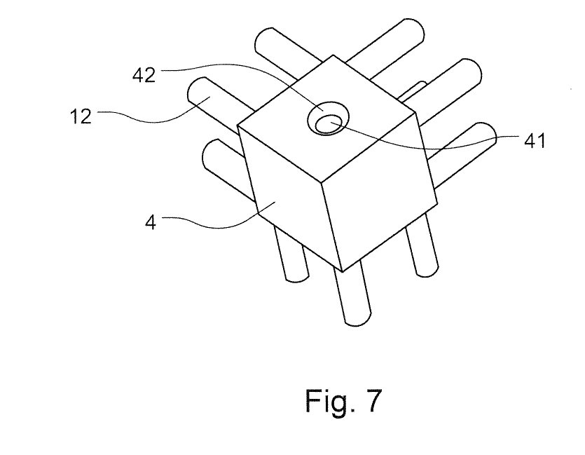

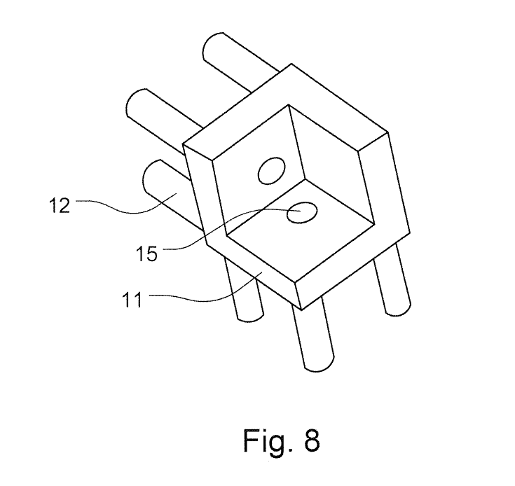

Please refer to FIG. 7. The frame according to the present invention further comprises a plurality of protection caps 4 covering and connected with the plurality of three-axis connecting members 1. As shown in the figure, after the three-axis connecting member 1 is covered by the protection cap 4, a rectangular solid, which is preferably a cube, is formed. Then the appearance of the corner of the frame of solar cell module is more complete. In addition, the protection cap 4 includes a third fixing screw hole 41. Thereby, a crew can pass through the third fixing screw hole 41, the first fixing screw hole 15, and the second fixing screw hole 22 sequentially and fix the protection cap 4, the three-axis connecting member 1, and the edge bar 3 together.

The first fixing screw hole 15 and the second fixing screw hole 22 according to the present invention include threads; the third fixing screw hole 41 in the protection cap 4 may not include threads if it allows the screw to pass through. Besides, the third fixing screw hole 41 can include a recess 42 on its inner edge for accommodating the screw head and avoiding extrusion from the protection cap 4.

Finally, please refer to FIG. 8. According to the variation of the frame of solar cell module, the present invention can use a design different from the normal three-axis connecting member. Namely, the two-axis connecting member as shown in the figure is used for combining with two edge bars. Similar to this variation, a multi-axis connecting member using the same technical characteristics of connecting method can be further applied with flexibility in the structure of the present invention. In this case, the connecting parts of the multi-axis connecting member are not necessarily perpendicular to one another. Instead, specific angles can be used according to the directions of the edge bars to be connected.

To sum up, the present invention discloses a frame structure of solar cell module, which adopts extruded aluminum as the frame member of solar cell module. At the junctions of the length, width, and height edges, connecting members using the three-axis joining and tenoning technology are used as fixing members. The tenon parts in both horizontal directions of the three-axis connecting member are first inserted into and joined with the mortises of the length-edge bar and the width-edge bar of extruded aluminum. Then the mortises on the height-edge bar are joined with the tenon parts of the connecting member in the vertical direction and thus completing assembling of the frame of solar cell module. By considering the safety after installing the frame, the spatial utility, and the multi-axis flexibility, the present invention undoubtedly provides a frame structure of solar cell module having full economic values.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A frame structure of solar cell module, comprising:
a plurality of three-axis connecting members, each comprising:
three connecting parts, rectangle-shaped, the center of an inner surface of each of said connecting parts having a first fixing screw hole penetrating said connecting parts, respectively, and said connecting parts perpendicular to one another; and
a plurality of tenon parts, prism-shaped, and disposed on an outer surface of said connecting parts; and
a plurality of edge bars, having a plurality of mortises and a second fixing screw hole on both sides, said plurality of tenon parts inserting into said plurality of mortises, and said second fixing screw hole corresponding to said first fixing screw hole.

2. The frame structure of solar cell module of claim 1, and further comprising a plurality of screws penetrating said second fixing screw hole from said first fixing screw hole for locking and fixing said plurality of three-axis connecting members and said plurality of edge bars.

3. The frame structure of solar cell module of claim 2, and further comprising a plurality of protection caps connecting with said plurality of three-axis connecting members.

4. The frame structure of solar cell module of claim 3, wherein said protection cap covers said three-axis connecting member and forming a rectangular solid.

5. The frame structure of solar cell module of claim 3, wherein said protection cap comprises a third a third fixing screw hole, and said screw penetrating sequentially said third fixing screw hole, said first fixing screw hole, and said second fixing screw hole, respectively, for locking and fixing said plurality of protection caps, said plurality of three-axis connecting members, and said plurality of edge bars.

6. The frame structure of solar cell module of claim 5, wherein said protection cap further comprises a recess on the inner edge of said third fixing screw hole.

7. The frame structure of solar cell module of claim 1, wherein the inner surfaces of said first fixing screw hole and said second fixing screw hole include threads.

8. The frame structure of solar cell module of claim 1, wherein the inner diameter of said plurality of mortises is equal to the width of said plurality of tenon parts.

9. The frame structure of solar cell module of claim 1, wherein said tenon part is a cylinder or a prism.

10. The frame structure of solar cell module of claim 1, wherein said second fixing screw hole is located at the centers on both sides of said plurality of edge bars.

11. The frame structure of solar cell module of claim 1, wherein said plurality of edge bars further include at least a groove.

12. A frame structure of solar cell module, comprising:
at least a three-axis connecting member, comprising:
a plurality of connecting parts, the center of an inner surface of each of said connecting parts having a first fixing screw hole penetrating said connecting parts, respectively; and
a plurality of tenon parts, prism-shaped, and disposed on an outer surface of said plurality of connecting parts; and
a plurality of edge bars, having a plurality of mortises and a second fixing screw hole on both sides, said plurality of tenon parts inserting into said plurality of mortises, and said second fixing screw hole corresponding to said first fixing screw hole.
